(19) United States
(12) Patent Application Publication
(10) Pub. No.: US 2009/0196714 A1
(43) Pub. Date: Aug. 6, 2009

(54) Device for the transport, storage, and transfer of substrates

(76) Inventors: Raphael Sylvestre, Montmoison (FR); Erwan Godot, Annecy (FR); Gloria Sogan, Epagny (FR)

Correspondence Address: PATTI , HEWITT & AREZINA LLC, ONE NORTH LASALLE STREET, 44TH FLOOR, CHICAGO, IL, 60602, US

(21) Appl. No.: 12/308,033

(22) PCT Filed: May 31, 2007
(86) PCT No.: PCT/FR2007/051363

§ 371 Date: Mar. 6, 2009

(30) Foreign Application Priority Data
Jun. 9, 2006 (FR) 0652080

(51) Int. Cl. H01L 21/673; H01L 21/683; B25J 11/00

(52) U.S. Cl. 414/217.1; 414/225.01; 901/50

(57) ABSTRACT

According to the invention, a transport box ‘1) may be connected to an interface (2) and contain a basket ‘3) in which the substrates (4) may be placed. The basket (3) consists of a set of plates (3a-3f), stacked one after the other and individually replaceable. The basket (3) is entirely shifted to the interior of the interface (2), then the means of movement isolating a selected plate by moving the adjacent places, allowing the robot (5) to come and extract the selected substrate. When in a transport position, the plates (3a-3f) are in contact with each other, therefore reducing the amount of space taken up by the substrates (4).

The invention pertains to the transport, storage, and transfer of substrates, particularly between the steps of manufacturing microelectronic components, for example for manufacturing microelectromechanical systems (MEMS) or micro-opto-electromechanical systems (MOEMS). More particularly, the invention pertains to a pod for transporting and storing substrates and an interface for transferring these substrates.

The substrates mainly come in the form of square-shaped masks or circular wafers made of a semiconducting material such as silicon.

In currently-used devices, between the various steps of manufacturing semiconductors, the substrates are transported and stored in transport pods which protect them from pollution by particles found in the atmospheres of cold sites. Usually, the transport pods contain one substrate or multiple stacked substrates. A substrate may be a mask or silicon wafer, 200 mm in diameter or 300 mm in diameter, for example. Currently, the commonly used transport pods contain from 1 to 25 substrates.

Inside a transport pod, the substrates are stacked near one another in a sort of single-piece rack which is also known as a cassette or basket.

A transport pod comprises a pod casing with an opening that may be blocked by a door, and a basket in which substrates may be stored.

The transport pods may be coupled with input-output interfaces of semiconductor manufacturing equipment. They are coupled using robotized locks. A first robot transports each substrate individually from the transport pod to an intermediary lock, which may be a transfer chamber, or load lock. The transfer chamber or load lock is at a low pressure. Next, the transfer chamber's robot transports the substrate from the load lock to a process chamber. The space available beneath the substrate that the robot is to handle must be sufficient to, firstly, allow the robot's arm to fit below the substrate. Secondly, this robot arm must be able to sufficiently rise, moving the substrate, so that the substrate is no longer resting on its mount, but rather is resting only on the robot's arm, which will then be able to move the substrate to the process chamber.

In this manner, the transport pod's basket must be sufficient in size so that the adjacent substrates that it contains are permanently separated by enough distance to allow a robot arm to fit in between. As a result, the transport pods, which must contain the basket, are relatively voluminous, and may not contain a large number of substrates.

Yet, the space available for storage in a cold site is reduced, due to the construction and maintenance costs that it represents. The total volume of the transport pods which can be stored there is limited, such that this constitutes a limit to the number of substrates that may be stored.

The transport pods may be designed to either contain an atmospheric-pressure atmosphere, or to contain a lower-pressure atmosphere or a vacuum. In the latter case, the wall of the pod must be reinforced so that it can mechanically support the outside pressure without significantly warping or degrading. The result is a heavier wall, and the weight of the pod may become too great to handle if the size of the pod is increased.

There is therefore a need to reduce the form factor and weight of the transport pods and/or to increase the number of substrates that each of them may contain, in order to best use the volume of the cold sites and ensure that the pods may be handled easily.

The transport pods generally have the advantage of being able to maintain a controlled atmosphere around the substrates, in which the presence of contaminants is avoided as much as possible.

A first type of transport pod, known by the acronym SMIF (Standardized Mechanical Interface), is currently used. Such a transport pod comprises a bell-shaped pod casing resting upon a base plate which blocks its lower opening and constitutes a door. The basket is generally placed or held atop the base plate. The substrates are stacked horizontally within the basket.

A detailed description of SMIF transport pods may be found, among other places, in U.S. Pat. No. 4,532,970.

For transferring substrates from a SMIF transport pod to a process chamber, the transport pod is placed upon an interface surface which opens up its lower door and causes the entire basket and the substrates it contains to lower into an interface chamber. The substrates are then removed from the basket one by one by a robot, so that they can be inserted into the process chamber.

A second type of transport pod, known by the acronym FOUP (Front-Opening Universal Pod), comprising a side-opening pod casing, is also currently used.

Under both circumstances, the substrates engaged within the basket must be sufficiently separated so that a selected substrate may be grasped by a robot arm, and moved away from its mount within the basket.

The present invention is particularly aimed at reducing the form factor of the transport pods, or conversely, to increase their capacity in terms of the number of substrates that they may contain for the same given volume, in order to optimize the space occupied within the cold sites in which they are used.

Another purpose of the invention is to simplify the equipment, by reducing transfers, and by eliminating transfer chambers or load locks as much as possible.

Another purpose of the invention is to reduce the risks of substrates becoming polluted when they move within the transport pods and when they are transferred into or out of a transport pod. To that end, the invention results from an in-depth observation of sources of pollution that may affect the substrates when such transport pods are used.

Furthermore, the invention intends to make it easier to decontaminate the transport pods and baskets between periods of use.

To achieve these purposes as well as others, the invention first discloses a transport pod for substrates such as semiconductor substrates, having a pod casing equipped with walls and comprising an opening, with a door blocking the opening in a sealed manner, and a basket, in which substrates may be stored, being housed in the pod casing.

The basket may be moved through the opening so that it can be inserted into the pod casing and be removed from the pod casing. The basket is made of a stacked series of parallel plates, each one supporting a substrate, with the plates overlapping one another when the basket is inside the pod casing, and the plates may be moved apart from one another, along a direction of movement perpendicular to the plane of the substrates, when the basket is outside of the pod casing.

Thanks to the ability of the plates to move with respect to one another, it may be arranged so that, when the plates are stacked, the substrates are relatively close to one another, so that they only take up a small volume, whereas when being transferred by a robot, the plates may be separated from one another to allow room for the robot arm to fit. Thus, during transport, as the substrates may be closer to one another, the transport pod may have a lower volume or contain a larger number of substrates.

Furthermore, thanks to their close proximity to one another both when the transport pod is being transported and when the basket is moved into and out of the transport pod, the substrates mutually protect one another, which considerably reduces the risk of particulate pollution on the active surfaces of the substrates.

Preferentially, when the plates are in a stacked position, the basket inserted into the pod casing fits closely into said pod casing. In this manner, the volume of the atmosphere surrounding the plates is reduced, which simultaneously reduces the risks of pollution by the gases or particles found in this atmosphere.

Preferentially, the plates will be designed so that, when they are in a stacked position, the adjacent substrates are in one another's immediate proximity. This optimizes the reduction in the transport pods' volume. For example, when the plates are in a stacked position, the distance between adjacent substrates may advantageously be less than about 5 mm.

In one advantageous embodiment, the basket is integral with and moved by the door. In this manner, to transfer a basket into or out of the pod casing, it is sufficient to operate the door of the transport pod.

In a first application, the transport pod may be a bottom-opening SMIF. In this case, the basket is preferentially supported by the door.

In another application, the transport pod may be a front-opening FOUP, and the basket is integral with the door.

Preferentially, when the plates are in a stacked position, the peripheral areas of the adjacent plates are close together over at least one portion of the edges of the substrates, ensuring that the substrates are at least partially confined within the basket. In this manner, the substrates are at least partially isolated from the atmosphere surrounding the basket within the transport pod, which further reduces the volume of the atmosphere around the substrates, and the risks of pollution are further reduced.

Preferentially, the transport pods comprise means for compressing the plates against one another within the pod casing whenever the casing is closed by the door. This reduces the risks that the basket may move relative to the pod casing, which could create pollution by friction or gas displacement.

Additionally, the plates are advantageously designed so as to grip the substrates between two adjacent plates during transport. This ensures that the substrates are very effectively kept in place, reducing the risks that the substrates may deteriorate if the transport pod suffers impacts while it is being handled. This further reduces the risks that the substrates may become polluted.

In one advantageous embodiment, each plate comprises:

a side recess open to the outside, capable of receiving a plate locking system,

opposing main surfaces with contour-fitting shapes to cooperate with the adjacent plates and to ensure that the plates are prevented from relative transversal movement parallel to the planes of the substrates,

a support surface for receiving the first surface of a peripheral portion of a substrate,

a holding surface to abut the second surface of the peripheral portion of another substrate,

the support and holding surfaces being designed to grip the peripheral portion of the substrate between two adjacent plates.

Preferentially, the holding surface comprises a rounded edge, constituting an area less harmful to the corresponding surface of the substrate, and keeping the substrate centered.

The holding face may advantageously comprise an elastic relief, such as an elastically flexible strip, which further impedes harm to the corresponding surface of the substrate.

Alternatively, means may be provided to hold the substrates onto the plates electrostatically.

In one advantageous embodiment, the plates are designed to allow them to rotate relative to one another, within their plane, along a range of angles that makes it possible to correct the alignment of the substrates which they carry.

According to another aspect, the invention discloses an interface intended to cooperate with at least one transport pod, so that it may be coupled with a piece of substrate treatment equipment, comprising

an interface chamber comprising an access hole for coupling to the transport pod, preferentially in a sealed manner by means of a gasket, and a through hole in contact with the equipment,

receiving means, for receiving and holding the transport pod, with its door facing the access hole,

basket-controlling means for moving the basket containing the substrates between the transport pod and the interface chamber,

a robot for grasping and transferring the substrates between the basket inside the interface chamber and the equipment,

plate-controlling means designed to selectively separate a chosen plate from one or more adjacent plates, along their direction of movement, so as to enable the robot to selectively take a substrate and move it towards or away from the chosen plate.

Preferentially, the interface further comprises door-controlling means for opening and closing the transport pod door.

In the event that the basket is coupled to the door of the transport pod, the door-controlling means may also serve as the basket-controlling means.

The interface may further comprise a robot for grasping and transferring the substrates between the basket placed within the interface chamber and the equipment.

In the event that a transport pod with horizontal plates is used, such as a SMIF, the plate-controlling means may comprise plate-locking means designed to selectively prevent the downward movement of a chosen plate, in order to separate the chosen plate from the adjacent plate below it.

Alternatively, the plate-locking means are further designed to selectively block the downward movement of the adjacent plate above the chosen plate, in order to keep the chosen plate away from the adjacent plate above it.

Advantageously, the plate-locking means are further designed to selectively block the downward movement of a chosen plate and the downward movement of the adjacent plate above it, in order to keep the chosen plate separate from both adjacent plates.

According to one advantageous embodiment of the interface, the plate-locking means may further be designed to pivot the plate that they retain within its plane, along a range of angles making it possible to correct the alignment of the substrate supported by the plate with respect to the other stacked substrates.

The transport pods with horizontal plates further make it possible to conceive of a particularly advantageous use, whereby the transport pods themselves constitute an extension of the interface, and consequently make it possible to reduce the volume of the interface.

The height of the interface may be reduced just enough to receive the basket with the close-together stacked substrates, and only the additional height needed to leave space between the upper plate and the upper substrate so that it may be grasped. The lower substrates may be grasped while the basket is partially engaged within the transport pod.

Owing to the small size of the interface, and according to the invention, integrating the interface with the interior of an equipment transfer chamber itself may be provided for, as is currently found in microelectronic component manufacturing facilities.

This saves room and streamlines the vacuum generation means.

Other objects, characteristics, and advantages of the present invention will become apparent from the following description of specific embodiments, with reference to the attached figures, in which:

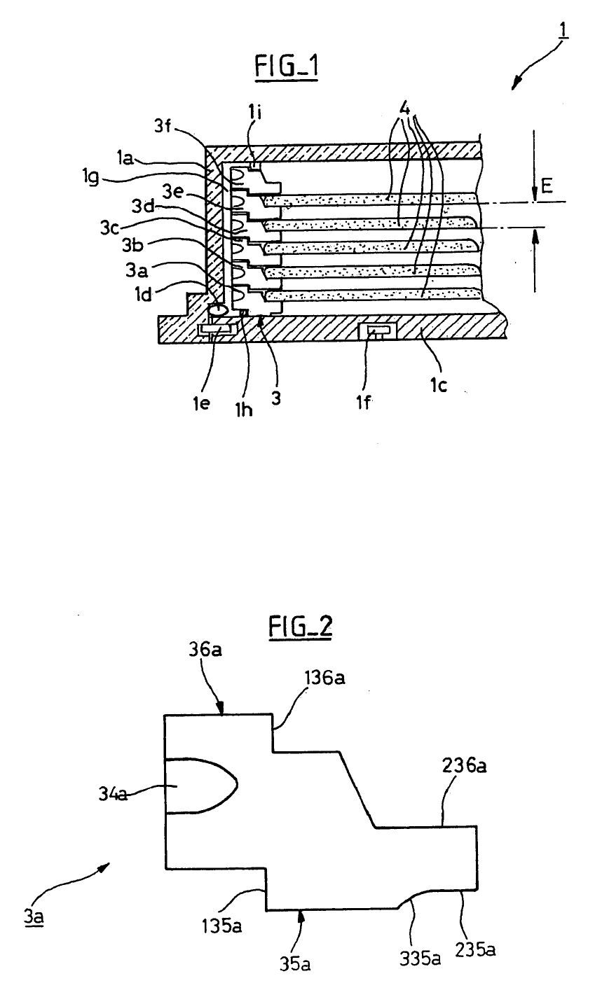

FIG. 1 is a partial cross-section schematic view of a transport and storage pod according to one embodiment of the invention, in a storage position;

FIG. 2 is a partial cross-section schematic view of a plate for supporting a substrate wafer;

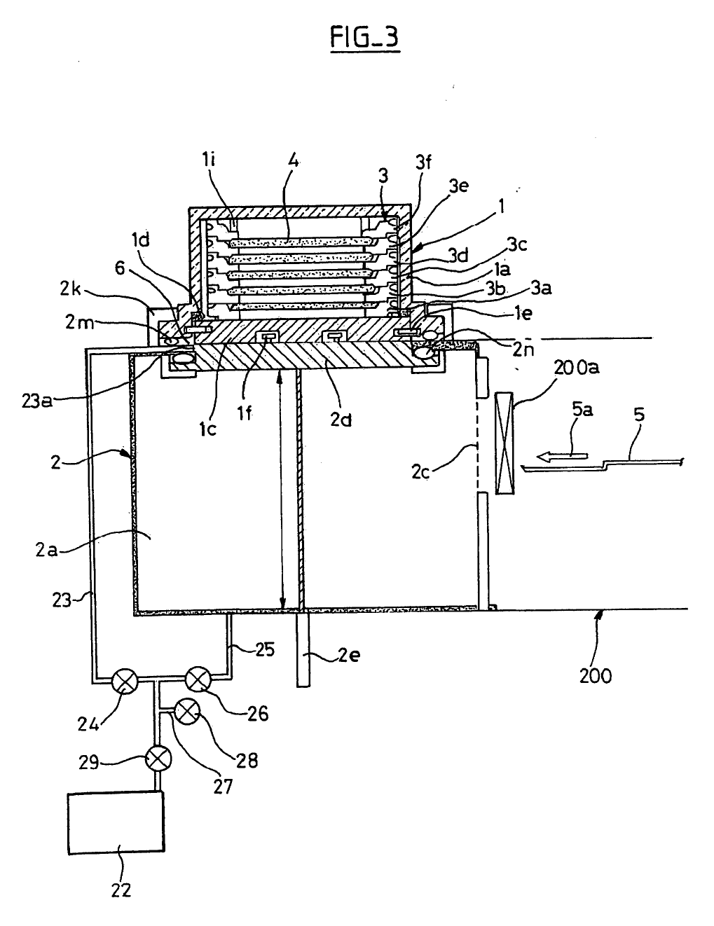

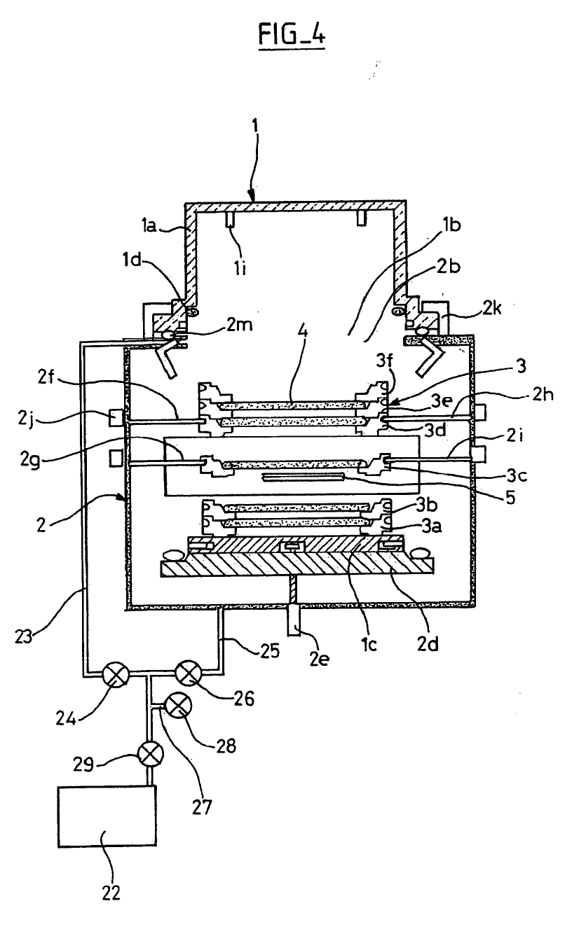

FIGS. 3 and 4 are partial cross-section schematic views showing two steps of removing a substrate from the inventive transport pod, so that it may be transferred into a process chamber; FIG. 3 is a front view in which the substrate's side opening may be seen; FIG. 4 is a side view after a 90° angle rotation with respect to FIG. 3, showing the substrate's posterior opening; and

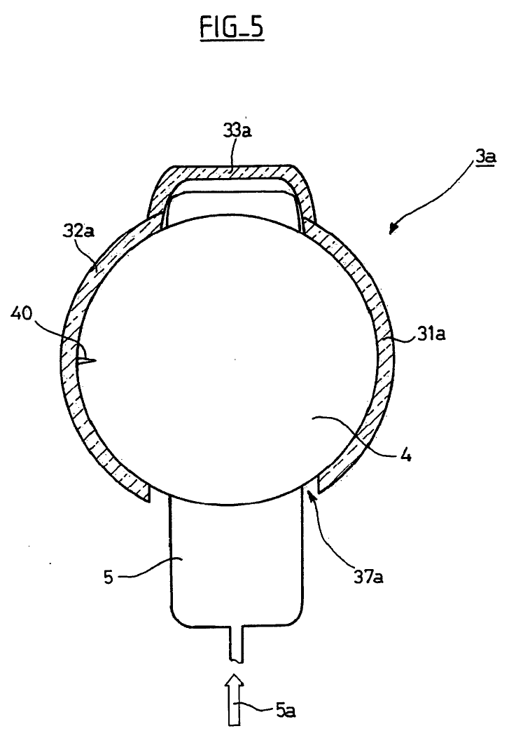

FIG. 5 is a top view of a substrate-supporting plate according to one embodiment of the invention.

In the embodiment illustrated in these figures, the inventive transport pod 1 is a SMIF. In FIG. 1, the transport pod 1 is shown as being isolated in a closed position. In FIG. 3, the transport pod 1 is in the closed position, coupled to an interface 2. In FIG. 4, the transport pod 1 is illustrated in an open position, coupled to the interface 2.

The transport pod 1, in this embodiment, comprises a pod casing 1a with a bottom opening 1b (FIG. 4) that may be blocked by a door 1c.

In the functional transport position, the transport pod 1 contains a basket 3 into which substrates 4 to be transported may be stored.

The basket 3 comprises a series of parallel plates each designed to store a substrate 4. Thus, in the figures, the plates 3a, 3b, 3c, 3d, 3e, and 3f may be seen. It should be understood that the invention is not limited to a basket with six plates as illustrated; rather, the transport pod 1 may contain a different number of plates depending on its volume and the volume taken up by each plate.

The pod casing 1a, in such a SMIF pod, comprises walls that approximately form a bell shape, with a pod casing side part and a horizontal upper part. The pod door 1c, which covers the lower opening 1b in a sealed manner 1d, is associated with a gasket and pod door-locking means 1e.

For opening and closing, the pod door 1c moves vertically, between the closed position illustrated in FIGS. 1 and 3 and the open position illustrated in FIG. 4.

The pod door-locking means 1e may, for example, comprise latches supported by the pod door 1c and operated, through radial sliding, by coupling means 1f themselves operated from the interface 2, engaging into recesses provided for within the peripheral wall of the pod casing 1a, as illustrated in the figures.

According to one embodiment, the coupling means 1f may be mechanical coupling means of a key engaging into a lock.

This mode of mechanical coupling, however, exhibits the disadvantage of generating mechanical friction between the key and its recess; this friction may produce polluting particles that eventually end up on the substrates. Thus, to reduce this risk of pollution, magnetic coupling means 1f may be envisioned.

When the pod is closed, as depicted in FIGS. 1 and 3, the plates 3a-3f are stacked on top of one another. Each plate 3a-3f supports a single substrate 4. In this position, the adjacent plates, such as plates 3a and 3b, are in direct contact with one another.

The plates 3a-3f may be made of plastic material.

When the plates are in a stacked position and the transport pod 1 is closed, as illustrated in FIGS. 1 and 3, the basket 3 inserted into the pod casing 1a is closely covered by the pod casing 1a. In this manner, the edges of the basket 3 are in the immediate proximity of the side wall of the pod casing 1a, leaving only a very small peripheral space 1g between them. The lower plate 3a is in direct contact with the pod door 1c. The upper plate 3f is in direct contact with the upper wall of the pod casing 1a, also leaving upper and lower spaces between them with very low volumes.

Furthermore, when the plates 3a-3f of the basket 3 are stacked atop one another and are contained within the transport pod 1, the pod door 1c being closed, the stack of plates 3a-3f is kept compressed by means for compressing the plates against one another inside the pod casing closed by the pod door 1c. In the embodiment depicted in the figures, a stack of plates 3a-3f is compressed by elastic stops 1h and 1i, which may, for example, be ring seals made of an elastic material such as polymers or perfluoroelastomers that are chemical-resistant

The plates 3a-3f may be separated from one another, along a direction of movement perpendicular to the plane of the substrates 4, when the door 1c is opened, and when the basket 3 is at least partially contained within the interface 2. FIG. 4 illustrates this possibility for movement: as can be seen, the middle plate 3c is raised with respect to the lower plates 3a and 3b which rest upon the pod door 1c, and the upper plates 3d, 3e, and 3f are themselves raised with respect to the middle plate 3c. Relative movement occurs along the vertical axis, perpendicular to the horizontal plane along which the substrates 4 are disposed. This possibility for vertical movement makes it possible to leave, on both sides of the middle plate 3c, enough space to first allow a robot arm 5 through (FIG. 4), then to lift the middle substrate 4a above the plate 3c, in order to then allow it to be moved horizontally away from the basket 3.

Conversely, when the plates 3a-3f are stacked one on top of the other, as depicted in FIGS. 1 and 3, the space between two adjacent substrates may be much less than the space needed to allow a robot arm 5 through and allow the vertical movement of the substrate before it is moved horizontally.

As can be seen in FIGS. 1 and 3, when the plates 3a-3f are in a stacked position, the peripheral areas of the adjacent plates are close together over at least one portion of the edge of the substrate 4, ensuring that the substrates 4 are at least partially confined within the basket 3.

In the embodiment illustrated in greater detail in FIGS. 2 and 5, each plate, such as plate 3a, is, in the top view of FIG. 5, a roughly horseshoe-shaped structure, with two opposite lateral branches 31a and 32a whose first ends are connected by a crossbar 33a, and whose second ends are separated from one another to allow a front passage 37a enabling the robot arm 5 to move. The lateral branches 31a and 32a have a profile suitable for the contours of the substrate 4 to be carried. For example, they may be curved to hold a disk-shaped substrate 4, or they may be straight to hold a rectangular substrate.

In the cross-section illustrated in FIG. 2, it may be seen that the plate 3a comprises a side recess 34a open to the outside. This side recess 34a is capable of receiving a plate locking system, as will be described with reference to FIG. 4. The plate 3a further comprises opposing main surfaces 35a and 36a with contour-fitting shapes to cooperate with the adjacent plates and to ensure that the plates are prevented from moving transversely parallel relative to the planes of the substrates 4. In practice, the surface 35a comprises a shoulder 135a, and the surface 36a comprises a shoulder 136a, the shoulders 135a and 136a being positioned in such a way as to enable the relative overlapping of the two stacked plates.

The upper surface 36a comprises a support surface 236a designed to receive the first surface of the peripheral portion of a substrate 4. The lower surface 35a comprises a holding surface 235a to abut a second surface of the peripheral portion of another substrate. The support surface 236a and holding surface 235a are designed to grip between them the peripheral portion of a substrate 4 between two adjacent plates, as can be seen in FIGS. 1 and 3.

In the embodiment depicted in FIG. 2, the holding surface 235a comprises a rounded edge 335a, which is involved in the gripping and ensures that the substrate 4 held by the plate 3a is relatively centered.

According to one advantageous embodiment, the holding surface 235a may comprise an elastic relief, not illustrated in the figures. Such an elastic relief may, for example, be an elastically flexible strip whose first end is integral with the holding surface 235a, and which operates through bending, with its opposite end area elastically abutting the substrate 4.

When in use, the substrates 4 rest upon the flat support surfaces 236a of the plates. These support surfaces 236a must be perfectly clean and free from polluting particles.

The rounded shape of the holding surfaces 235a makes it possible to guide and pinch a substrate against its upper edge, which prevents it from coming into contact with the active surface of the substrate, avoiding an additional risk of contamination.

When a transport pod 1 is closed for storage or transport, the holding surface 235a is abutting a substrate immediately below the plate 3a, and holds the substrate wafer in a fixed position in order to prevent it from becoming damaged while the transport pod 1 is being moved. All the substrates 4 are kept pinched along their edge, and all the plates 3a-3f are fastened by compressing the compression means 1h-1i between the upper wall of the pod casing 1a and the pod door 1c. The transport pod 1 may then be handled in all directions without any chance that the substrates 4 will move within the basket 3. The substrates 4 are held in place reliably, regardless of whether the transport pod 1 is fully or partially filled with substrates 4. Indeed, even if some of the plates are not supporting substrates, the fact that all the plates 3a-3f are compressed together and that each pair of two consecutive plates is pinching the substrate between them makes it possible to keep all the substrates found there fixed in place with respect to the transport pod 1.

Looking at FIG. 1, the space E between two consecutive substrates, when the plates 3a-3f are stacked atop one another, is reduced to 2 or 3 mm, instead of the 10 or so mm which are currently needed in known transport pods. This disposition, made possible by the relative movement of the plates with respect to the others, allows a current transport pod designed for transporting a single substrate to be used, in accordance with the invention, to contain up to five substrates, without needing to modify the geometry of the transport pod's casing.

Now let us consider FIGS. 3 and 4, which illustrate the transport pod 1 coupled to an interface 2 in accordance with one embodiment of the invention.

In this embodiment, the interface 2 makes it possible to couple a transport pod 1 with a piece of substrate treating equipment 200, schematically depicted in FIG. 3. The purpose is to transfer substrates between the transport pod 1 and the equipment 200, by means of the interface 2.

The pod casing 1a is held by the interface 2 by receiving means 2k, such as removable flanges.

The interface 2 comprises an interface chamber 2a, having an upper access hole 2b corresponding with the opening 1b of the transport pod 1, and having a side through-hole 2c corresponding with the equipment 200, which may be blocked by an equipment door 200a.

An interface door 2d is designed to selectively block the access hole 2b, and to do so, may move vertically through the action of a cylinder 2e.

When the transport pod 1 is mounted onto the interface 2, the transport pod's door 1c is joined with the interface door 2d by coupling means 1f. In this manner, the cylinder 2e constitutes a door-controlling means for opening and closing the door 1c of the transport pod 1, and simultaneously constitutes a basket-controlling means for moving the basket 3 containing the substrates 4 between the transport pod 1 and the chamber 2a of the interface 2.

For a coupling using mechanical coupling means 1f of an interface door 2d key engaged into a lock in the pod door 1c, the polluting particles resulting from friction escape into the inner vacuum atmosphere of the transport pod 1 and the interface 2, because the pod door 1c/interface door 2d assembly is located within the lower-pressure atmosphere which itself contains the substrates 4 to be treated. Therefore, magnetic coupling means 1f will be preferred.

In the embodiment depicted, the equipment 200 comprises a robot 5 for grasping and transferring substrates 4 between the basket 3 located within the horizontal interface 2a and the equipment 200. It may be seen that the robot ensures horizontal movement along the arrow 5a, to engage below a substrate as depicted in FIGS. 4 and 5. Alternatively, the robot may form part of the interface 2.

The interface 2 further comprises plate-controlling means suitable for selectively separating a chosen plate from one or more adjacent plates along their direction of movement (the vertical direction, in the embodiment depicted in the figures), so as to enable the robot to selectively take a substrate 4 and move it towards or away from the chosen plate.

In the embodiment depicted in the figures, the plate-controlling means comprise plate-locking means which selectively prevent the vertical movement of certain chosen plates.

In practice, the plate-locking means are locking pins 2f, 2g, 2h, and 2i controlled by corresponding motors or cylinders, such as the cylinder 2j of the locking pin 2f, in order to be moved radially towards or away from the plates. The end of each locking pin may engage within a recess of the corresponding plates through the action of a cylinder.

For example, we shall consider the plate 3d located directly above the plate 3c bearing the substrate 4a which has been selected for removal; when this plate 3d is at the desired height, the locking pins 2f and 2h prevent the plate 3d from lowering, while the lowering of the plate 3c is performed through the action of the cylinder 2e. Finally, when the substrate 4a is at the desired height, the locking pins 2g and 2i prevent the plate 3c from lowering, while the lowering of the plates 3b and 3a is performed through the action of the cylinder 2e. In this manner, a sufficient space is left both below and above the substrate 4a as depicted in FIG. 4, so that the robot 5 may engage below the substrate 4a and lift it in order to detach it from the plate 3c.

It should be understood that the locking pins 2f-2i engage within the respective side recesses 34a of the plates 3a-3f.

Advantageously, the locking pins, such as the pin 2f, comprise two support points, for better stability.

According to one advantageous possibility, to further limit pollution caused by particle creation, the plate locking means may comprise one or more electromagnets disposed on the exterior of the interface 2, and each plate 3a-3f may comprise a magnetic element so that it may be controlled by the electromagnet in order to selectively lock the plate into a vertical position.

The heights of the locking pins 2f-2i are chosen in such a way so that the free space above the selected substrate 4a is sufficient to enable the substrate 4a to be lifted by the robot 5 so that it may then be moved to the equipment 200.

The heights of the locking pins are also chosen in such a way that the free space below the selected substrate 4a is sufficient to enable the robot 5 to fit below the substrate 4a.

The locking pins 2f-2i are placed on the sides of the interface 2 which are perpendicular to the side having the through hole 2c leading to the equipment 200. The locking pins act on the side parts of the plates 3a-3f, on either side of the direction of the movement of the substrates 4 towards or away from the equipment 200. In this manner, the locking pins 2f-2i do not prevent the robot 5 and the substrates 4 from moving between the interface 2 and the equipment 200.

The treatment of the substrates 4 within the equipment 200 requires that each substrate 4 be oriented in a precise manner within the process chamber. Alignment is easier when it is already performed within the transport pod 1 or at least within the interface 2. To do so, in accordance with the invention, means may be provided to perform or at least correct this alignment, through controlled pivoting of the plates with respect to one another: the locking pins 2g and 2i which support the plate 3c (FIG. 4) are motorized so as to pivot the plate 3c that they retain within its plane, along a suitable range of angles enabling the correction of the alignment of the plate 3c. This alignment is detected by noting the position of a detector such as a notch 40 (FIG. 5) or another mark provided upon the edge of the substrate 4a.

Alternatively, the alignment may be corrected by rotating means embedded in the robot 5 of the interface 2 or of the equipment 200.

Now let us consider the series of states of the inventive device during the operating steps for transferring substrates 4 between a transport pod 1 and a piece of equipment 200.

The transport pod 1 is coupled to the interface 2, with the doors 1c and 2d being closed. The receiving means 2k fasten the body casing 1a to the interface 2, as depicted in FIG. 3. Detachable coupling means 1f join the pod door 1c to the interface pod 2d, and operate the locking means 1e to unlock the pod door 1c from the pod casing 1a.

Door operating means, made up of cylinder 2e, then vertically move a block between both doors 1c and 2d apart from body casing 1a within the interface chamber 2a of interface 2.

In FIG. 4, with the door being opened, the cylinder 2e has caused the basket 3 in the substrates 4 to penetrate into the interface 2 through the upper access hole 2b. The plates then have the spaces they need to be moved away from one another. As the locking pins 2f-2i have isolated the plates 3c and the substrate 4a that they carry, the robot 5 may then lift the substrate 4a and move it horizontally to the equipment 200 through the side through hole 2c of the interface 2.

If another substrate is to be selected, for example the substrate carried by the plate 3d, the cylinder 2e moves the doors 1c and 2d in reverse, upward, which causes the stack of the lower plates 3a and 3b to rise to the height of the plate 3c; the locking pins 2g and 2i may retract. The cylinder 2e lifts the stack of the three plates 3a, 3b, and 3c to the height of the plate 3d. The locking pins 2f and 2h may be retracted. Next, the cylinder 2e moves the stack of plates one step downward, the locking pins 2f and 2h lock the plate 3e, the cylinder 2e continues to descend, the locking pins 2g and 2i lock the plate 3d, and the cylinder 2e continues to descend so that the plate 3d is then isolated so that the substrate it carries may be taken.

Once the transfer of substrates is complete, the cylinder 2e raises the doors 1c and 2d until the transport pod 1 and the interface 2 close, as depicted in FIG. 3. The transport pod door 1c is locked with its locking means 1e, and the receiving means 2k may be unlocked to separate the transport pod 1 from the interface 2.

According to another embodiment of the invention, not depicted in the figures, the transport pod 1 may be a FOUP, i.e. a side-opening pod. In such a case, it couples to the interface 2 on one of its sides. The movement of the basket 3 in two successive motions must then be provided for: a first horizontal motion, with the pod door and interface door opening, followed by a second vertical motion for isolating the chosen plate as depicted in FIG. 4.

According to one advantageous embodiment, the inventive transport pod 1 makes it possible to maintain a controlled atmosphere around the substrates 4, in order to prevent them from becoming contaminated during the transport and storage steps, by ensuring sufficient sealing, in a simple, low-cost manner. Preferentially, the controlled inner atmosphere is at a lower pressure.

To achieve this, it may advantageously be provided that the peripheral wall of the pod casing 1a is sealed, and that the pod door 1c fits onto the pod casing 1a by placing gaskets 1d between them as depicted in the figures. The pod door 1c locking means must preferentially be designed to keep the gaskets 1d of the pod door 1c elastically compressed when it is closed.

In the closing motion of the transport pod 1, the cylinder 2e of the interface 2 axially pushes the pod door 1c and interface door 2d towards the transport pod 1, compressing the door gasket 1d slightly to excess, so as to enable the pod door locking means 1e to slide freely with little or no friction, preventing the generation of polluting particles. This excessive push movement is made possible by the elastic stops 1i and 1h, which allow excessive movement of the pod door 1c into the transport pod 1 without being halted by the stack of plates 3. After locking, the pod door is released, being elastically pushed by the elastic stops 1h and 1i and by the gasket 1d of the pod door 1c.

An interface front gasket 2m is placed between the transport pod 1 and the interface 2 to ensure that, between the transport pod 1 in the wall surrounding the access hole 2b of the interface 2, they are sealed from the outer atmosphere around the access hole 2b and the opening 1b of the transport pod 1.

It should be understood that the receiving means 2k with removable flanges push the transport pod 1 towards the interface 2, compressing the interface front gasket 2m, which may be warped as depicted.

The interface front gasket 2m constitutes a peripheral sealing means which isolates from the outer atmosphere a coupling area 6 between the respective front faces of the transport pod 1 and the interface 2 around the opening 1b of the transport pod 1 and the access hole 2b of the interface 2. The coupling area 6 is the trapped gas volume, in the position depicted in FIG. 3, between the pod door 1c, the interface door 2d, the pod gasket 1d, the interface front gasket 2m, and an interface door gasket 2n. When the pod door 1c and the interface door 2d are opened, this volume is in direct communication with the internal cavity of the transport pod 1 and of the interface 2. Initially, the volume of this coupling area 6 is at atmospheric pressure, meaning that it has a non-negligible amount of gas, and it appears useful to provide pumping means to create a vacuum within this coupling area 6, and thereby to remove the majority of the polluting elements that it may contain. To do so, connection pumping means are provided.

In the embodiment depicted in FIGS. 3 and 4, the connection pumping means comprise a connection pumping tube 23, whose inlet 23a communicates with the volume of the coupling area 6, and whose outlet is connected with a vacuum pumping device such as a pump 22, with a connection pumping control valve 24 being interposed.

The vacuum pumping device is also connected, via an interface pumping tube 25, to the inner space of the interface 2, with a connection pumping control valve 26 being interposed.

The connection pumping means are further designed to selectively establish, within the volume of the coupling area 6, a pressure roughly equal to the surrounding pressure outside the device. To achieve this, a balancing tube 27, equipped with a balancing valve 28, connects the connection pumping tube 23 and/or the volume of the coupling area 6 with an injection of a purging gas such as nitrogen or with the outside of the device. An isolation valve 29 may be used to isolate the pump 22 during the vacuum release phases.

The connection pumping means further comprise control means, such as microprocessors or microcontrollers, in order to control the gas pressure found within the interface 2 and within the volume of the coupling area 6, by controlling the pump 22 as well as the valves 24, 26, 28, and 29 based on signals received from various sensors, not depicted in the figures, and based on a saved program.

In this manner, the connection pumping means are designed to establish pressure equilibriums during the various operating phases.

For example, during the step of coupling a transport pod 1 to the interface 2, the volume of the coupling area 6 is at atmospheric pressure at the outset, while the inner atmosphere of the transport pod 1 may be at a low initial pressure, and the interface 3 may be at a second low pressure, potentially different from the pressure of the transport pod 1. Before the pod door 1c and the interface door 2d are opened, the connection pumping means 22-29 may establish, within the volume of the coupling area 6, a gas pressure approximately equal to the pressure within the transport pod 1.

If necessary, the connection pumping means 22-29 establish, within the interface 2, a gas pressure approximately equal to the pressure within the transport pod 1, with the equipment door blocking the side through hole 2c of the interface 2. The pod door 1c and interface door 2d may then be opened. Next, the connection pumping means selectively establish, within the interface 2 and within the transport pod 1, a gas pressure approximately equal to the pressure within the equipment 200. The equipment door 200a that blocks the side through hole 2c may then be opened, for transferring the substrates between the transport pod 1 and the equipment 200.

During a later step, for example after the substrates have been transferred, the equipment door 200a may then be closed to block the side through hole 2c, and the connection pumping means 22-29 may then be designed to selectively establish within the interface 2 and within the transport pod 1a gas pressure approximately equal to the pressure desired within the transport pod 1. The pod door 1c and interface door 2d are then closed, and the connection pumping means 6 return the volume of the coupling area to atmospheric pressure so that the transport pod 1 can be decoupled from the interface 2.

Between periods of use, once the transport pod 1 is adapted to the interface 2 and the pod door 1c is open, a vacuum may be created within the interface 2, which also makes it possible to create a vacuum within the pod, and thereby to decontaminate the transport pod 1 through degassing.

The present invention is not limited to the embodiments which have been explicitly described; rather, it includes the many variations and generalizations that a person skilled in the art may envision.

1. A transport pod (1) for substrates (4) such a semiconductor substrates, having a pod casing (1a) equipped with walls and comprising an opening (1b), a door (1c) blocking the opening (1b) in a sealed matter, and a basket (3) inserted into the pod casing (1a) in which substrates (4) may be stored, characterized in that:
the basket (3) may be moved through the opening (1b) so that it may be inserted in the pod casing (1a) and be removed from the pod casing (1a), and
the basket (3) is made up of a stacked series of parallel plates (3a-3f), each one supporting a substrate (4), the plates (3a-3f) being stacked atop one another when the door (1c) is closed, and the plates being moveable away from one another, along the direction of movement perpendicular to the plane of the substrates (4), when the door (1c) is open.

2. A transport pod in accordance with claim 1, wherein, when the plates (3a-3f) are in a stacked position, the distance (E) between the adjacent substrates (4) is less than about 5 mm.

3. A transport pod in accordance with claims 1 and 2, wherein the basket (3) is integral with the door (1c).

4. A transport pod according to one of the above claims, wherein, when the plates (3a-3f) are in a stacked position, the peripheral areas of the adjacent plates are close together over at least one portion of the edge of the substrates (4).

5. A transport pod according to one of the above claims, further comprising means (1c, 1h, 1i) for compressing the plates (3a-3f) against one another within the pod casing (1a) when the pod casing is closed by the door (1c).

6. A transport pod according to one of the above claims, wherein each plate (3a-3f) comprises:
a side recess (34a) open to the outside capable of receiving a plate locking system (2f-2i),
opposing main surfaces (35a, 36a) with interlocking shapes to cooperate with the adjacent plates and to ensure that the plates are prevented from relative movement transversally parallel to the planes of the substrates (4),
a support surface (236a) for receiving the first surface of the peripheral portion of a substrate (4),
a holding surface (235a) to push against the second surface of the peripheral portion of another substrate,
the support surface (236a) and holding surface (235a) being designed to lock the peripheral portion of a substrate (4) between two adjacent plates.

7. A transport pod according to claim 6, wherein the holding surface (235a) comprises a rounded edge (335a).

8. A transport pod according to one of claims 6 or 7, wherein the holding surface (235a) comprises an elastic relief (335).

9. A transport pod according to one of the above claims, wherein the plates (3a-3f) are designed to allow them to rotate relative to one another, within their plane, along a range of angles that makes it possible to correct the alignment of the substrates (4) which they carry.

10. An interface (2) between at least one transport pod (1) in accordance with one of claims 1 to 13, and a piece of substrate treatment equipment (200), comprising
an interface chamber (2a) comprising an access hole (2b) for being coupled to the transport pod (1), preferentially in a sealed manner by means of a gasket (2m), and a through hole (2c) cooperating with the equipment (200),
receiving means (2k), for receiving and holding the transport pod (1), with its door (1c) facing the access hole (2b),
basket-controlling means for moving the basket (3) containing the substrates (4) between the transport pod (1) and the interface chamber (2a),
a robot (5) for grasping and transferring the substrates (4) between the basket (3) inside the chamber (2a) of the interface (2) and the equipment (200),
plate-controlling means (2e, 2f-2i) designed to selectively separate a chosen plate (3c) from one or more adjacent plates (3b, 3d), along their direction of movement, so as to enable the robot (5) to selectively take a substrate (4a) and move it towards or away from the chosen plate (3c).

11. An interface according to claim 10, further comprising door-controlling means (2e) for opening and closing the door (1c) of the transport pod (1).

12. An interface according to one of claims 10 or 11, intended to co-operate with at least one transport pod having horizontal plates, wherein the plate-controlling means comprise plate-locking means (2f-2i) designed to selectively prevent the downward movement of a chosen plate (3c), in order to separate the chosen plate (3c) from the adjacent plate (3b) below it, and/or plate-locking means (2f-2i) designed to selectively prevent the downward movement of the adjacent plate above (3d) the chosen plate (3c), in order to separate the chosen plate (3c) from the adjacent plate above it (3d).

13. An interface according to claim 12, wherein the plate-locking means (2f-2i) comprise locking pins whose end engages into to a recess (34a) of the corresponding plate (3a) by the action of a cylinder (2j).

14. An interface according to claim 12, wherein the plate-locking means comprise motorized locking pins (2f-2i).

15. An interface according to claim 12, wherein the plate-locking means (2f-2i) comprise one or more electromagnets acting upon a magnetic portion of the plate (3a-3f) in order to ensure locking.
